(19) United States
(12) Patent Application Publication
(10) Pub. No.: US 2015/0111312 A1
(43) Pub. Date: Apr. 23, 2015

(54) DEPOSITION DATA PROCESSING APPARATUS, AND APPARATUS AND METHOD FOR MANUFACTURING ORGANIC EL DEVICE

(71) Applicant: NITTO DENKO CORPORATION, Ibaraki-shi, Osaka (JP)

(72) Inventors: Ryohei Kakiuchi, Ibaraki-shi (JP); Satoru Yamamoto, Ibaraki-shi (JP); Takayoshi Yamano, Ibaraki-shi (JP)

(73) Assignee: NITTO DENKO CORPORATION, Ibaraki-shi, Osaka (JP)

(21) Appl. No.: 14/383,626

(22) PCT Filed: Mar. 5, 2013
(86) PCT No.: PCT/JP2013/055926

§ 371 Date: Sep. 8, 2014

(30) Foreign Application Priority Data
Mar. 9, 2012 (JP) 2012-052975
Feb. 19, 2013 (JP) 2013-030034

(51) Int. Cl. H01L 51/56; C23C 16/52; G01B 11/00; H01L 51/00

(52) U.S. Cl. CPC H01L 51/56; H01L 51/0008; H01L 51/0031; C23C 16/52; G01B 11/00
USPC 438/7; 118/712; 118/699; 702/155

(57) ABSTRACT

Provided are a deposition data processing apparatus, an apparatus and a method for manufacturing an organic EL device, which make it possible to check deposition states of constituent layers of each of organic EL elements that are continuously formed on a substrate being conveyed. The deposition data processing apparatus includes a scanning section configured to scan at least two of a plurality of constituent layers that constitute each of the organic EL elements; and a processor configured to accumulate data of the constituent layers scanned by the scanning section at a specific position in a longitudinal direction of the substrate as data of a specific one of the organic EL elements.

### CROSS-REFERENCE TO RELATED APPLICATION

This application claims priority to Japanese Patent Applications Nos. 2012-052975 and 2013-030034, the disclosures of which are incorporated herein by reference in their entirety.

### FIELD

The present invention relates to a deposition data processing apparatus that processes the deposition data of an organic EL (electroluminescence) element formed on a substrate. The present invention relates also to an organic EL device-manufacturing apparatus for manufacturing an organic EL device, and further to a method for manufacturing an organic EL device.

### BACKGROUND

Conventionally, a roll-to-roll process is known as a method for manufacturing an organic EL device. The roll-to-roll process is a process described as follows. While a strip-shaped substrate wound in a roll is continuously unwound so as to be conveyed, constituent layers of the organic EL element are formed on the substrate by discharging evaporation materials from a plurality of evaporation sources toward the substrate being conveyed so that the evaporation materials thus discharged are deposited on a deposition surface of the substrate. Thereafter, the substrate is wound up into a roll (see Patent Literature 1).

### CITATION LIST

### Patent Literature

Patent Literature 1: JP 2008-287996 A

### SUMMARY

### Technical Problem

In the manufacturing apparatus and the manufacturing method according to Patent Literature 1, the evaporation materials are sequentially discharged from the plurality of evaporation sources, and the constituent layers are layered one after another. Thus, deposition states of the constituent layers cannot be known at all. Accordingly, there is a demand for checking deposition states of constituent layers of a specific one of organic EL elements that are continuously formed on the substrate being conveyed.

In view of such circumstances, an object of the present invention is to provide a deposition data processing apparatus, and an apparatus and a method for manufacturing an organic EL device, which make it possible to check deposition states of the respective constituent layers of each of organic EL elements that are continuously formed on a substrate being conveyed.

### Solution to Problem

A deposition data processing apparatus according to the present invention is configured to process deposition data of a plurality of organic EL elements that are formed in line in a longitudinal direction of a strip-shaped substrate being conveyed by depositing evaporation materials on the substrate. The apparatus includes: a scanning section configured to scan at least two of a plurality of constituent layers that constitute each of the organic EL elements; and a processor configured to accumulate data of the respective constituent layers scanned by the scanning section at a specific position in the longitudinal direction of the substrate, as data of a specific one of the organic EL elements.

Further, an apparatus for manufacturing an organic EL device according to the present invention includes: the aforementioned deposition data processing apparatus; a conveying section configured to convey the substrate; and a plurality of evaporation sources configured to discharge evaporation materials onto the substrate being conveyed, wherein the evaporation materials discharged from the evaporation sources are deposited on the substrate so as to form each of the organic EL elements composed of the plurality of constituent layers.

The apparatus for manufacturing an organic EL device according to the present invention may include a shielding section having a shielding member configured to shield the substrate, and may have a configuration in which the shielding member includes a first opening configured to expose a constituent layer-forming position of the substrate at which the constituent layers are formed, so that the evaporation materials are deposited on the constituent layer-forming position of the substrate, the shielding section includes, in order to form a scan trigger that triggers the scanning section to scan the constituent layers, a second opening configured to expose a trigger-forming position of the substrate at which the scan trigger is formed, so that the evaporation materials are deposited on the trigger-forming position of the substrate, and the scanning section scans the constituent layers on the basis of detection of the scan trigger.

The apparatus for manufacturing an organic EL device according to the present invention may have a configuration in which the processing apparatus includes a deposition controller configured to control the discharge of the evaporation materials by the evaporation sources, and a deposition tester configured to test deposition states of the constituent layers on the basis of the data of the constituent layers scanned by the scanning section, wherein the deposition controller is configured to stop the discharge of the evaporation materials by the evaporation sources on the basis of the test results by the deposition tester.

A method for manufacturing an organic EL device according to the present invention is configured to manufacture an organic EL device using the aforementioned apparatus for manufacturing an organic EL device.

### BRIEF DESCRIPTION OF DRAWINGS

FIG. 1 shows an overall plan view of an apparatus for manufacturing an organic EL device according to an embodiment of the present invention.

FIG. 2 shows a plan view of a main part of the apparatus for manufacturing an organic EL device according to the aforementioned embodiment.

FIG. 3 shows a plan view of a main part of the apparatus for manufacturing an organic EL device according to the aforementioned embodiment when a specific shielding member is located at a shielding position.

FIG. 4 shows a vertical sectional view of a main part of the apparatus for manufacturing an organic EL device according to the aforementioned embodiment when the specific shielding member is located at the shielding position.

FIG. 5 shows a side exploded view of a main part of the apparatus for manufacturing an organic EL device according to the aforementioned embodiment when the specific shielding member is located at the shielding position.

FIG. 6 shows a plan view of a main part of the apparatus for manufacturing an organic EL device according to the aforementioned embodiment when the specific shielding member is located at an unshielding position.

FIG. 7 shows a vertical sectional view of a main part of the apparatus for manufacturing an organic EL device according to the aforementioned embodiment when the specific shielding member is located at the unshielding position.

FIG. 8 shows a schematic system diagram of the apparatus for manufacturing an organic EL device according to the aforementioned embodiment.

FIG. 9 shows a plan view of a main part of the organic EL device manufactured using the apparatus for manufacturing an organic EL device according to the aforementioned embodiment.

FIG. 10 shows an enlarged sectional view, taken along the line X-X in FIG. 9, of the organic EL device.

FIG. 11 shows an enlarged vertical sectional view of an organic EL device manufactured using an apparatus for manufacturing an organic EL device according to another embodiment of the present invention.

FIG. 12 shows a side exploded view of a main part of an apparatus for manufacturing an organic EL device according to still another embodiment of the present invention.

FIG. 13 shows a plan view of a main part of the organic EL device manufactured using the apparatus for manufacturing an organic EL device according to the aforementioned embodiment.

### DESCRIPTION OF EMBODIMENTS

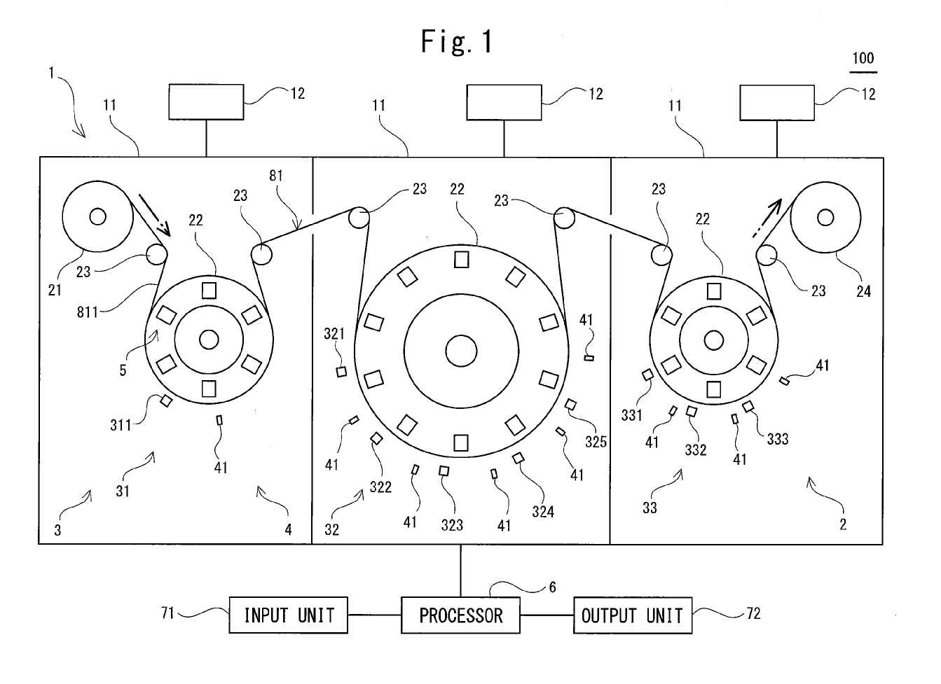

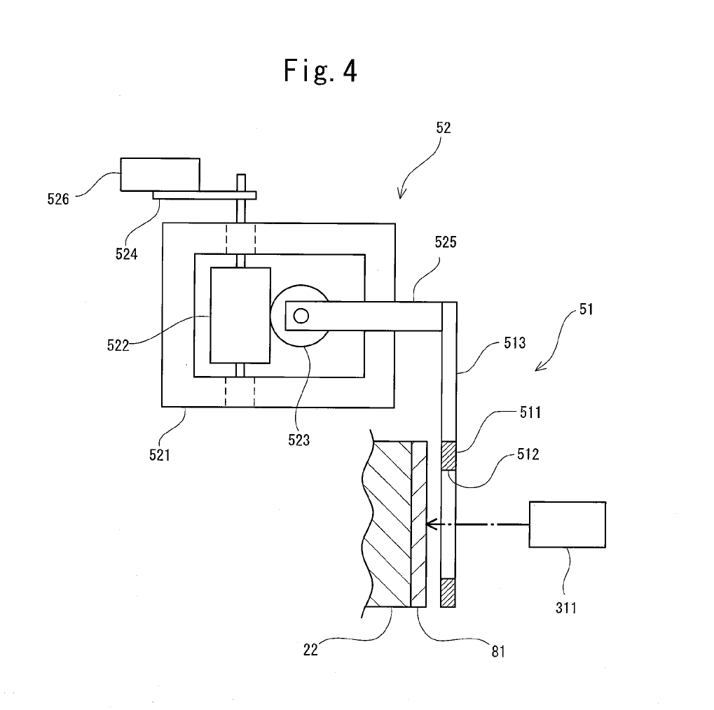

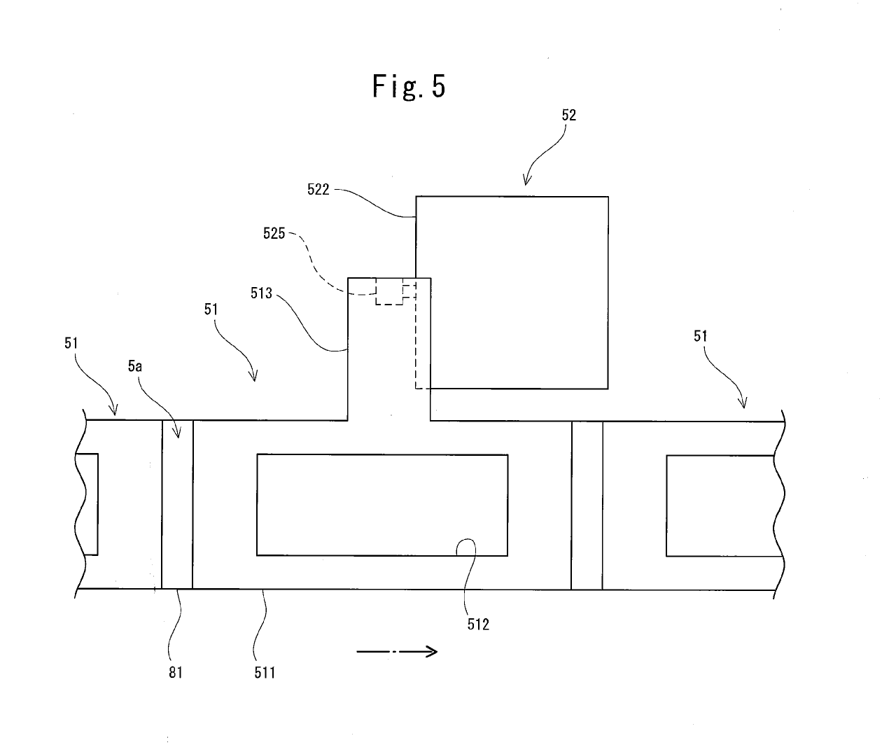

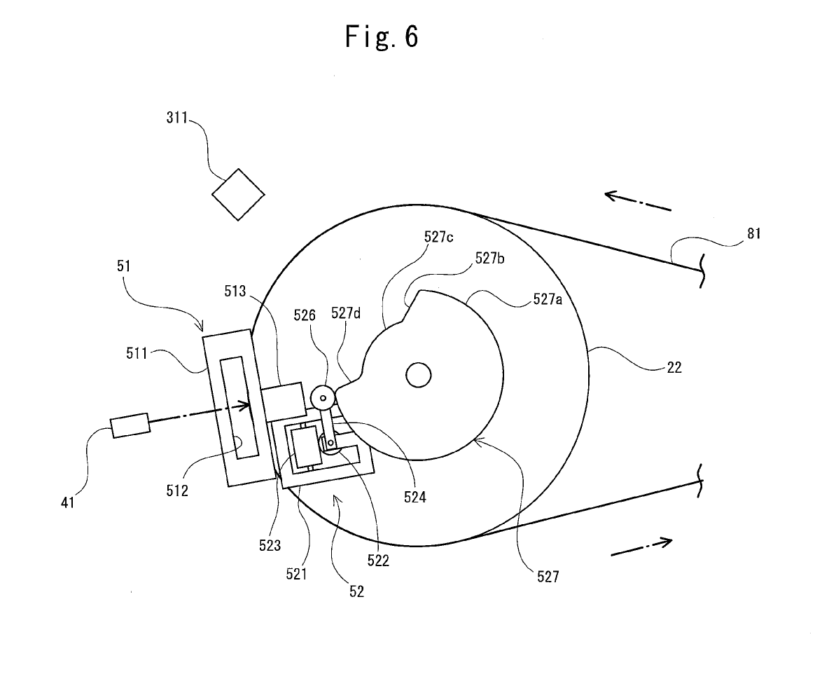

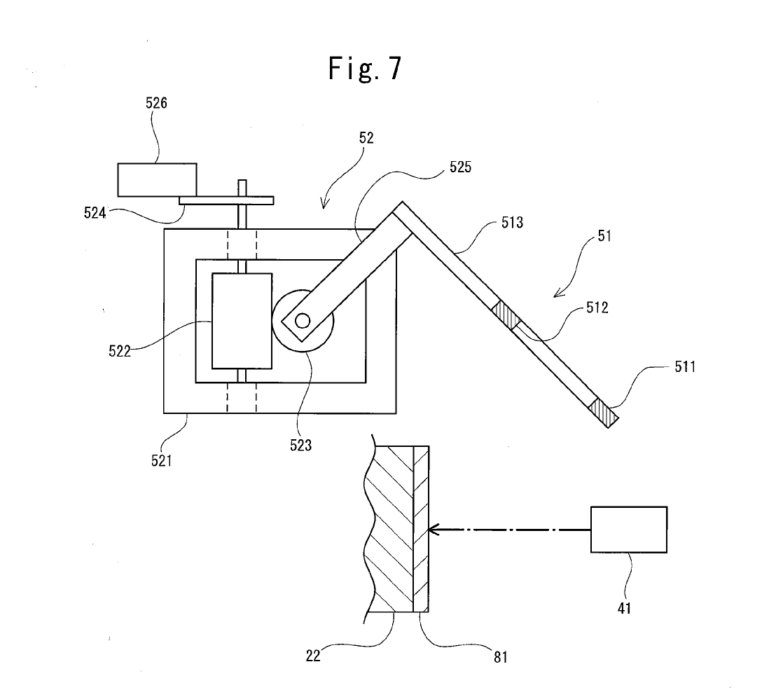

Hereinafter, an embodiment of an apparatus for manufacturing an organic EL device according to the present invention is described with reference to FIG. 1 to FIG. 10.

An apparatus for manufacturing an organic EL device (hereinafter, may be referred to simply as “manufacturing apparatus”) 100 according to this embodiment includes a vacuum chamber 1 in which a vacuum is maintained, a conveying section 2 that conveys a strip-shaped substrate 81 in the longitudinal direction so that the substrate 81 passes through the inside of the vacuum chamber 1, a deposition section 3 that discharges an evaporation material onto a deposition surface 811 that is one surface of the substrate 81 being conveyed, a scanning section 4 that scans the constituent layers of each of organic EL elements 80, a shielding section 5 that shields the substrate 81, and a processor 6 that processes the data scanned by the scanning section 4.

Further, the manufacturing apparatus 100 includes a deposition data processing apparatus (hereinafter, may be referred to simply as “processing apparatus”) 101 that processes deposition data of a plurality of organic EL elements 80 formed in line in the longitudinal direction of the substrate 81. The processing apparatus 101 includes the scanning section 4, the processor 6, an input unit 71, such as a keyboard and a mouse, configured to input various data, and an output unit 72, such as a display and a printer, configured to output the processed data.

The vacuum chamber 1 includes three vacuum chambers 11, and vacuum generators (for example, vacuum pumps) 12 connected respectively to the vacuum chambers 11 so as to create a vacuum inside the vacuum chambers 11. The sections 2, 3, 4, and 5 are housed within the vacuum chambers 11.

The conveying section 2 includes a substrate feeder 21 that unwinds the strip-shaped substrate 81 wound in a roll so as to feed it, a plurality of support rollers 22 and 23 that support the substrate 81 by hanging the substrate 81 around their outer circumferences, and a substrate collector 24 that winds the substrate 81 into a roll so as to collect it. It should be noted that the substrate 81 is conveyed with its deposition surface 811 facing laterally all the time.

The plurality of support rollers 22 and 23 include first to third can rollers 22 that support the substrate 81 when the substrate 81 is subjected to deposition in the deposition section 3, and a plurality of conveying rollers 23 arranged in the course of the substrate feeder 21, the can rollers 22, and the substrate collector 24. The substrate 81 is hung on the plurality of support rollers 22 and 23.

The deposition section 3 includes a first deposition unit 31 that deposits an evaporation material on the substrate 81 supported by the first can roller 22, a second deposition unit 32 that deposits an evaporation material on the substrate 81 supported by the second can roller 22, and a third deposition unit 33 that deposits an evaporation material on the substrate 81 supported by the third can roller 22. The deposition units 31 to 33 are lateral deposition units that are respectively arranged laterally of the can rollers 22.

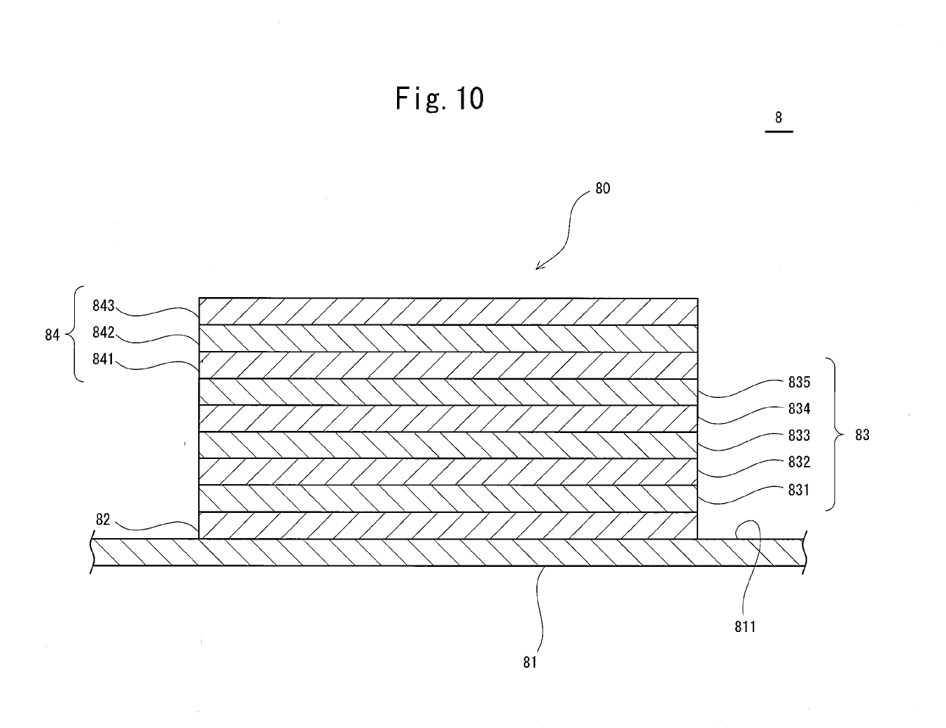

The first deposition unit 31 includes an anode layer-evaporation source 311 that forms an anode layer 82 (see FIG. 10) on the deposition surface 811 of the substrate 81 by vaporizing and discharging an evaporation material. That is, the first deposition unit 31 forms a single anode layer-constituent layer that constitutes the anode layer 82.

The second deposition unit 32 includes a hole injection layer-evaporation source 321 that forms a hole injection layer 831 (see FIG. 10) on the deposition surface 811 of the substrate 81 by vaporizing and discharging an evaporation material, a hole transporting layer-evaporation source 322 that is arranged downstream of the hole injection layer-evaporation source 321 and forms a hole transporting layer 832 (see FIG. 10) by vaporizing and discharging an evaporation material, and a light emitting layer-evaporation source 323 that is arranged downstream of the hole transporting layer-evaporation source 322 and forms a light emitting layer 833 (see FIG. 10) by vaporizing and discharging an evaporation material.

The second deposition unit 32 further includes an electron transporting layer-evaporation source 324 that is arranged downstream of the light emitting layer-evaporation source 323 and forms an electron transporting layer 834 (see FIG. 10) by vaporizing and discharging an evaporation material, and an electron injection layer-evaporation source 325 that is arranged downstream of the electron transporting layer-evaporation source 324 and forms an electron injection layer 835 (see FIG. 10) by vaporizing and discharging an evaporation material. That is, the second deposition unit 32 forms five organic EL layer-constituent layers that constitute an organic EL layer 83 (see FIG. 10).

The third deposition unit 33 includes first to third cathode layer-evaporation sources 331 to 333 that form first to third cathode layer-constituent layers 841 to 843 (see FIG. 10) on the deposition surface 811 of the substrate 81 by vaporizing and discharging evaporation materials. That is, the third deposition unit 33 forms a stack of three cathode layer-constituent layers that constitute a cathode layer 84.

Each of the evaporation sources 311, 321 to 325, and 331 to 333 is configured to vaporize a material contained therein by heating with a heater (not shown or numbered), and to discharge the thus vaporized material (evaporation material) onto the deposition surface 811 of the substrate 81 through a discharge opening. Each of the evaporation sources 311, 321 to 325, and 331 to 333 is arranged, with its discharge opening arranged at a lateral side facing the deposition surface 811 of the substrate 81, in order to laterally discharge an evaporation material.

Further, each of the evaporation sources 311, 321 to 325, and 331 to 333 is arranged at a position close to the substrate 81. Specifically, each of the evaporation sources 311, 321 to 325, and 331 to 333 is arranged at a position where the distance (shortest distance) between the substrate 81 and the discharge opening of each of the evaporation sources 311, 321 to 325, and 331 to 333 is 10 mm or less.

The scanning section 4 includes a plurality of scanners 41 that scan a specific region of the deposition surface 811 of the substrate 81. Further, the scanners 41 are respectively arranged downstream of the evaporation sources 311, 321 to 325, and 331 to 333. Thus, using the scanners 41, the scanning section 4 scans deposition states (such as a deposition region and deposition thickness) of the constituent layers 82, 831 to 835, and 841 to 843 of the organic EL element 80 which have been deposited by the evaporation sources 311, 321 to 325, and 331 to 333.

The scanners 41 are respectively arranged laterally of the can rollers 22 so as to face the deposition surface 811 of the substrate 81. Further, each of the scanners 41 is arranged at a position close to the substrate 81. It should be noted that the scanner 41 is a CCD camera in this embodiment.

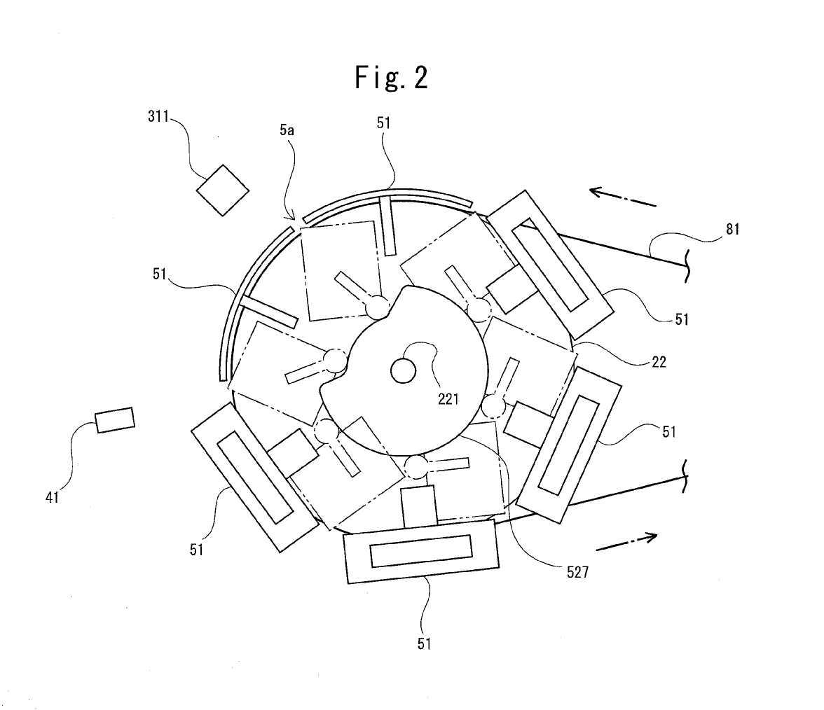

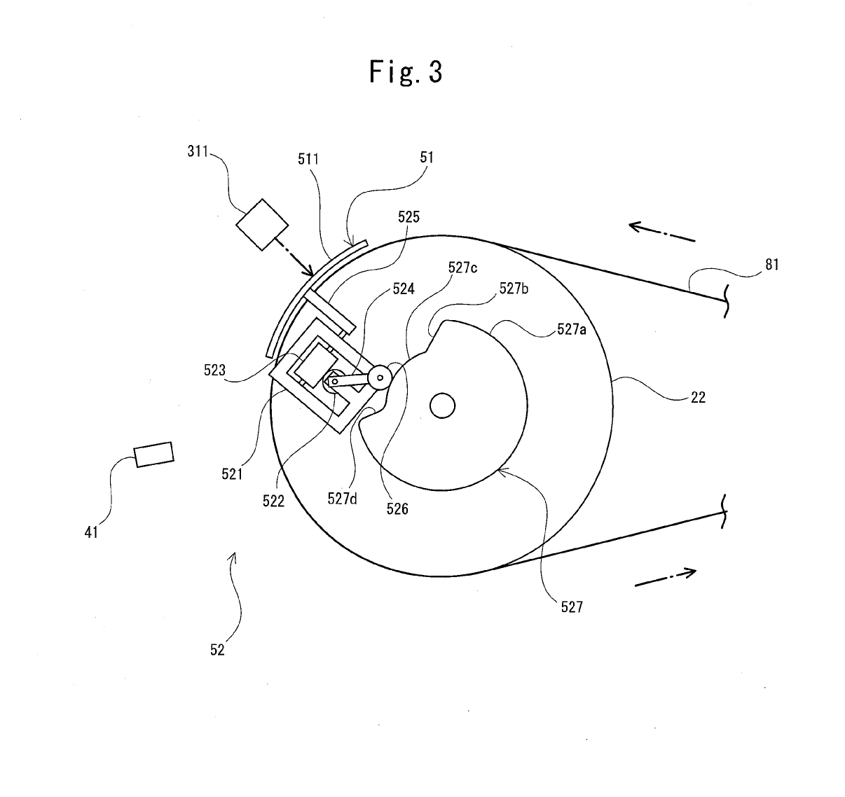

As shown in FIG. 2 to FIG. 7, the shielding section 5 includes a plurality of shielding members 51 that shield the substrate 81, and a plurality of switching mechanisms 52 that respectively switch the positions of the shielding members 51 by rotationally moving the shielding members 51. It should be noted that FIG. 2 shows all (six) of the shielding members 51 provided in the first can roller 22, whereas FIG. 3 to FIG. 7 show only a specific (one) shielding member 51.

Further, although FIG. 2 to FIG. 7 show the shielding members 51 and the switching mechanisms 52 provided in the first can roller 22, the shielding members 51 and the switching mechanisms 52 of substantially the same configurations are provided also in each of the second and third can rollers 22. In this embodiment, ten each of the shielding members 51 and the switching mechanisms 52 are provided in the second can roller 22. Six each of the shielding members 51 and the switching mechanisms 52 are provided in the third can roller 23.

Each of the shielding members 51 includes a shield 511 that shields the substrate 81, and a first opening 512 that exposes a constituent layer-forming position so that an evaporation material is deposited on a specific position (hereinafter, referred to also as “constituent layer-forming position”) of the substrate 81. Further, each of the shielding members 51 includes a base 513 that is connected to its switching mechanism 52.

The position of the shielding member 51 is switched by the switching mechanism 52 between a shielding position where the shield 511 is arranged between the evaporation source 311 and the substrate 81 so as to shield the substrate 81, and an unshielding position where the shield 511 is withdrawn from between the evaporation source 311 and the substrate 81 so as to unshield the substrate 81. In this embodiment, the shielding member 51 is a so-called flip-type shield plate.

The shield 511 is formed into a strip-shaped (specifically, rectangular) plate, while the first opening 512 is formed into a rectangular shape inside the shield 511. Further, the shield 511 is arranged spaced apart from the substrate 81 when it is located at the shielding position. For example, the distance between the shield 511 and the substrate 81 is desirably 1 mm or less.

In the shielding section 5, the shielding members 51 are arranged side by side along the circumferential direction of the can rollers 22, and the shields 511 located at the shielding position are arranged spaced apart from each other, thereby forming a second opening 5a therebetween. The shielding section 5 allows a specific position of the substrate 81 (hereinafter, referred to also as “trigger-forming position”) to be exposed through the second opening 5a. Thereby, the evaporation materials are deposited on the trigger-forming position of the substrate 81, so that a scan trigger 85 (see FIG. 10) that triggers the scanning section 4 to scan the constituent layers 82, 831 to 835, and 841 to 843 is formed.

Each of the switching mechanisms 52 includes a body 521 that is fixed to the can roller 22 so as to rotate integrally with the can roller 22. Further, the switching mechanism 52 includes a first rotor 522 that is supported by the body 521 so as to rotate about an axis parallel to a drive shaft 221 of the can roller 22, and a second rotor 523 that is supported by the body 521 so as to rotate about an axis extending along a direction orthogonal to the axis of the first rotor 522 and is driven by the first rotor 522.

Further, the switching mechanism 52 includes a first link 524 having one end connected to the shaft of the first rotor 522, and a second link 525 having one end connected to the shaft of the second rotor 523 and the other end connected to the base 513 of the shielding member 51. Furthermore, the switching mechanism 52 includes a cam follower 526 that is rotatably attached to the other end of the first link 524, and a cam 527 that is in slidable contact with the cam follower 526.

The first rotor 522 and the second rotor 523 are each provided with a magnetic material thereinside. Thus, the magnetic material of the second rotor 523 receives a magnetic force from the magnetic material of the first rotor 522 so that the second rotor 523 rotates with the rotation of the first rotor 522. The first rotor 522 and the second rotor 523 are arranged spaced apart from each other.

The cam 527 is formed into a circular plate. The cam 527 is arranged concentrically with the drive shaft 221 that drives the can roller 22. However, the cam 527 is fixed to the vacuum chambers 11 so as not to rotate integrally with the drive shaft 221 and the can roller 22.

The cam 527 includes a first region 527a for maintaining the shield 511 at the unshielding position, a second region 527b for moving the shield 511 from the unshielding position to the shielding position, a third region 527c for maintaining the shield 511 at the shielding position, and a fourth region 527d for moving the shield 511 from the shielding position to the unshielding position.

The switching mechanism 52 causes the shielding member 51 to rotate about the tangential direction of the outer circumference of the can roller 22 (direction orthogonal to the drive shaft 221 of the can roller 22), thereby allowing the shield 511 to move toward and away from the substrate 81. It should be noted that the switching mechanism 52 is provided with a bias member (not shown or numbered), so that the cam follower 526 is biased so as to be maintained in contact with each of the regions (the first region 527a to the fourth region 527d) of the cam 527.

In the first can roller 22, the shield 511 is switched so as to be located at the shielding position and the unshielding position one time each, during one rotation of the can roller 22. In order to allow the scanning section 4 to scan the deposition states of all the constituent layers 82, 831 to 835, and 841 to 843, the shield 511 is switched between the shielding position and the unshielding position the same number of times as the number of the evaporation sources 311, 321 to 325, and 341 to 343 arranged in the respective can rollers 22, during one rotation of the can rollers 22.

Specifically, in the second can roller 22, the shield 511 is switched so as to be located at the shielding position and the unshielding position five times each, during one rotation of the can roller 22. Further, in the third can roller 22, the shield 511 is switched so as to be located at the shielding position and the unshielding position three times each, during one rotation of the third can roller 22. The scanners 41 scan the deposition surface 811 of the substrate 81 when the shield 511 is located at the unshielding position.

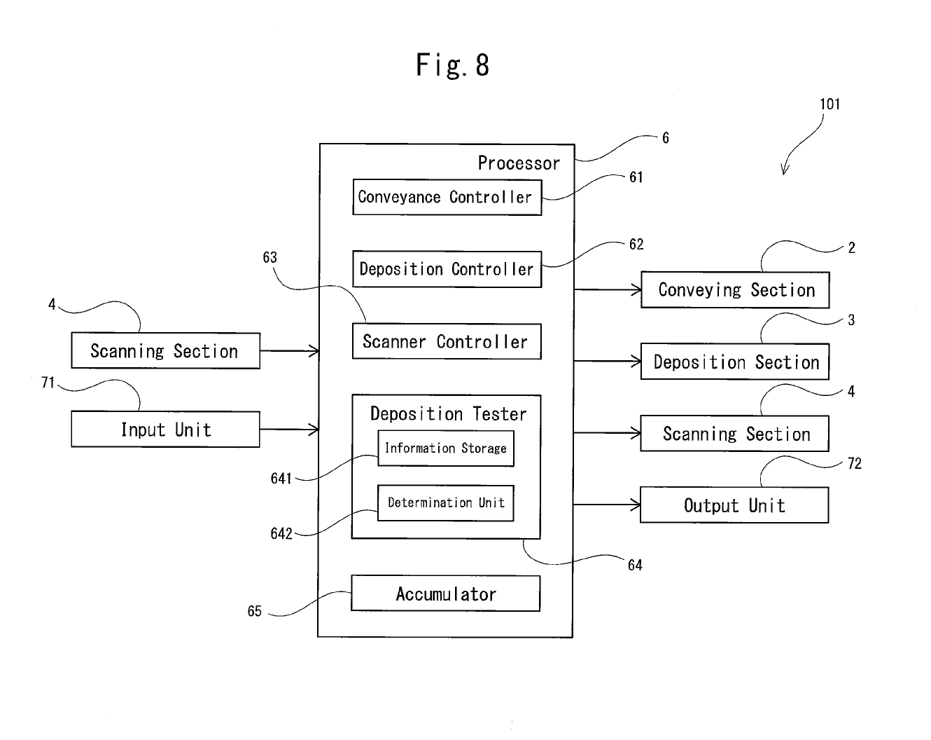

As shown in FIG. 8, the processor 6 includes a conveyance controller 61 that controls the conveying section 2, a deposition controller 62 that controls the deposition section 3, and a scanner controller 63 that controls the scanning section 4. Further, the processor 6 includes a deposition tester 64 that tests the deposition state on the basis of the data scanned by the scanning section 4, and an accumulator 65 that accumulates the data scanned by the scanning section 4.

The deposition controller 62 controls the discharge of the evaporation materials by the evaporation sources 311, 321 to 325, and 331 to 333. The deposition controller 62 causes the evaporation sources 311, 321 to 325, and 331 to 333 to stop discharging the evaporation materials on the basis of the test results by the deposition tester 64. Specifically, upon determining the anode layer 82 formed at a specific constituent layer-forming position to be abnormal, the deposition tester 64 causes the evaporation sources 321 to 325 and 331 to 333 arranged downstream of the anode layer-evaporation source 311 to stop discharging the evaporation materials onto the constituent layer-forming position.

The scanner controller 63 controls the scanners 41 so that the scanners 41 scan the deposition surface 811 of the substrate 81 on the basis of the detection of the scan trigger 85 of the substrate 81. Specifically, the scanner controller 63 controls the scanners 41, so that the scanners 41 scan the constituent layers on the deposition surface 811 of the substrate 81 at appropriate positions, after a specific time has elapsed from the detection of the scan trigger 85 by the scanners 41.

The deposition tester 64 includes an information storage 641 that stores the information of deposition data (such as a deposition region and a deposition thickness depending on a deposition concentration) for testing, and a determination unit 642 that determines whether the deposition state is normal or abnormal by comparing the information stored in the information storage 641 with the deposition data of the constituent layers scanned by the scanning section 4. Upon determining the deposition at a specific constituent layer-forming position to be abnormal, the deposition tester 64 transmits the information of the constituent layer-forming position to the deposition controller 62.

The accumulator 65 accumulates the data of the constituent layers 82, 831 to 835, and 841 to 843 scanned by the scanning section 4 at a specific position, that is, at a specific constituent layer-forming position in the longitudinal direction of the substrate 81, as data of one of the organic EL elements 80. Thus, the data of the constituent layers 82, 831 to 835, and 841 to 843 are accumulated for each of the organic EL elements 80.

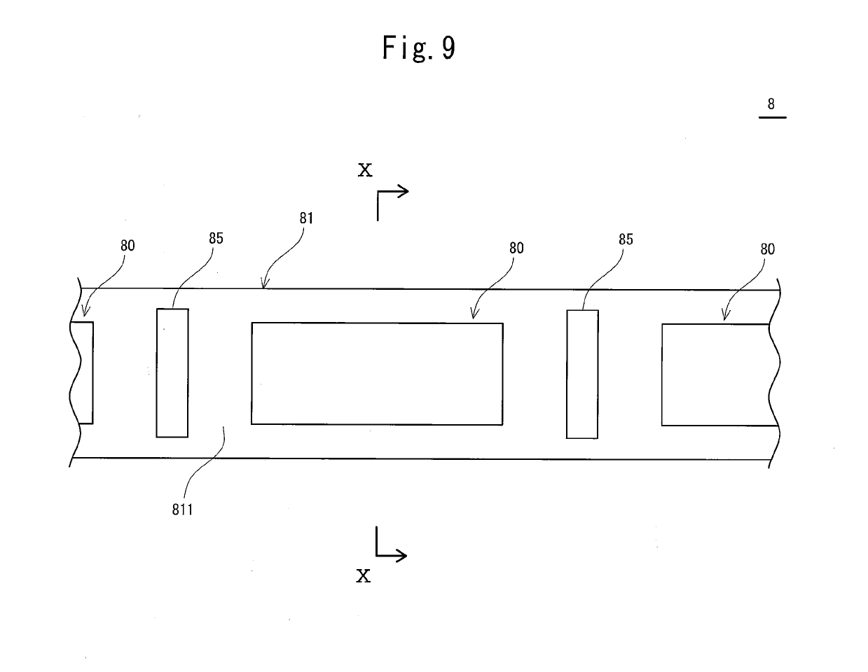

The apparatus for manufacturing an organic EL device 100 according to this embodiment is as described above. Next, the configuration of an organic EL device 8 manufactured using the apparatus for manufacturing an organic EL device 100 according to this embodiment is described with reference to FIG. 9 and FIG. 10.

The organic EL device 8 includes the substrate 81, the anode layer 82 composed of a single layer, the organic EL layer 83 that is a five-layered stack, and the cathode layer 84 that is a three-layered stack. Further, the organic EL device 8 has the scan trigger 85 that serves as a trigger to scan the constituent layers 82, 831 to 835, and 841 to 843 of each of a plurality of the organic EL elements 80 formed in line in the longitudinal direction of the substrate 81.

The size (width, thickness, and length) of the substrate 81 can be appropriately set corresponding to the size of the organic EL element 80 formed on the substrate 81, the configuration of the manufacturing apparatus 100, etc., and is not specifically limited. Further, the thickness of each of the layers 82 to 84 is generally designed to be about several nm to several tens of nm, but can be appropriately designed depending on the constituent layer-forming materials to be used, the light emission properties, etc. Thus, the thickness is not specifically limited.

As a material for forming the substrate 81, a flexible material is used so as not to be damaged in conveyance. Examples of such a material include metal materials such as stainless steel, copper, aluminum, and titanium, a non-metal inorganic material such as thin film glass, and synthetic resin materials including thermoplastic resins and thermosetting resins such as polyimide resin, polyester resin, epoxy resin, polyurethane resin, polystyrene resin, polyethylene resin, and polyamide resin.

As a material for forming the anode layer 82, gold, silver, and aluminum can be mentioned, for example. Although this embodiment employs a configuration in which the anode layer 82 is composed of a single anode layer-constituent layer, there is no limitation to such a configuration. For example, the anode layer only needs to be formed of at least one anode layer-constituent layer.

The organic EL layer 83 is a five-layered stack composed of five organic EL layer-constituent layers. The five organic EL layer-constituent layers are the hole injection layer 831, the hole transporting layer 832, the light emitting layer 833, the electron transporting layer 834, and the electron injection layer 835, in order from the anode layer 82 side.

As a material for forming the hole injection layer 831, copper phthalocyanine (CuPc), 4,4′-bis[N-4-(N,N-di-m-tolylamino)phenyl]-N-phenylamino]biphenyl (DNTPD), and HAT-CN can be mentioned, for example.

As a material for forming the hole transporting layer 832, 4,4′-bis[N-(1-naphthyl)-N-phenyl-amino]biphenyl (α-NPD) and N,N′-diphenyl-N,N′-bis(3-methyl phenyl)-1,1′biphenyl-4,4′diamine (TPD) can be mentioned, for example.

As a material for forming the light emitting layer 833, tris(8-hydroxyquinoline)aluminum (Alq3) and 4,4′-N,N′-dicarbazolyl biphenyl (CBP) doped with iridium complex (Ir(ppy)3) can be mentioned, for example.

As a material for forming the electron injection layer 834, lithium fluoride (LiF), cesium fluoride (CsF), and lithium oxide (Li2O) can be mentioned, for example.

As a material for forming the electron transporting layer 835, tris(8-hydroxyquinoline)aluminum (Alq3), bis(2-methyl-8-quinolinolato)-4-phenylphenolato-aluminum (BAlq), OXD-7(1,3-bis[5-(p-tert-butylphenyl)-1,3,4-oxadiazole-2-yl])benzene, and lithium fluoride (LiF) can be mentioned, for example.

It should be noted that, although this embodiment employs a configuration in which the organic EL layer 83 is composed of five organic EL layer-constituent layers, there is no limitation to such a configuration. For example, the organic EL layer 83 only needs to be formed of at least one organic EL layer-constituent layer. Specifically, the layer structure of the organic EL layer 83 is not specifically limited as long as it includes at least the light emitting layer 833.

As a material for forming the cathode layer 84, an alloy containing magnesium (Mg), silver (Ag), or the like, and lithium fluoride (LiF) can be mentioned, for example. In this embodiment, the first cathode layer-constituent layer is a LiF layer, the second cathode layer-forming layer is a Mg layer, and the third cathode layer-constituent layer is an Ag layer. It should be noted that, although this embodiment employs a configuration in which the cathode layer 84 is composed of three cathode layer-constituent layers, there is no limitation to such a configuration. For example, the cathode layer only needs to be formed of at least one cathode layer-constituent layer.

The scan trigger 85 is arranged between the plurality of the organic EL elements 80 that are arranged in line in the longitudinal direction of the substrate 81. The scan trigger 85 is formed so as to have a width dimension smaller than those of the organic EL elements 80 in the longitudinal direction of the substrate 81.

As described above, in the apparatus for manufacturing an organic EL device 100 according to this embodiment, the scanning section 4 scans all the plurality of the constituent layers 82, 831 to 835, and 841 to 843 that constitute each of the organic EL elements 80 formed in line in the longitudinal direction of the substrate 81. The processor 6 accumulates the data of the constituent layers 82, 831 to 835, and 841 to 843 scanned by the scanning section 4 at a specific position in the longitudinal direction of the substrate 81, as data of a specific one of the organic EL elements 80.

This makes it possible to easily check the data of the constituent layers 82, 831 to 835, and 841 to 843 for each of the organic EL elements 80. Accordingly, it is possible to check deposition states of the constituent layers 82, 831 to 835, and 841 to 843 in a specific one of the organic EL elements 80 that are continuously formed on the substrate 81 being conveyed.

Further, in the apparatus for manufacturing an organic EL device 100 according to this embodiment, the shielding section 5 is provided with the shielding members 51 that shield the substrate 81. Each of the shielding members 51 is provided with the first opening 512, and thus the constituent layer-forming position of the substrate 81 at which constituent layers are formed is exposed therethrough. Thus, the evaporation materials are deposited onto the constituent layer-forming position of the substrate 81, and the constituent layers 82, 831 to 835, and 841 to 843 as desired are formed.

Further, in the apparatus for manufacturing an organic EL device 100 according to this embodiment, the shielding section 5 is provided with the second opening 5a as a gap between the shields 511, and therefore the trigger-forming position of the substrate 81 at which the scan trigger 85 that triggers the scanning section 4 to scan the constituent layers 82, 831 to 835, and 841 to 843 is formed is exposed therethrough.

Thus, the evaporation materials are deposited on the trigger-forming position of the substrate 81, so that the scan trigger 85 is formed. The scanning section 4 scans the constituent layers 82, 831 to 835, and 841 to 843 on the basis of detection of the scan trigger 85. Therefore, the scanners 41 can scan the constituent layers 82, 831 to 835, and 841 to 843 while accurately recognizing the position of the constituent layers 82, 831 to 835, and 841 to 843.

Further, in the apparatus for manufacturing an organic EL device 100 according to this embodiment, the deposition tester 64 tests deposition states of the constituent layers 82, 831 to 835, and 841 to 843, on the basis of the data of the constituent layers 82, 831 to 835, and 841 to 843 scanned by the scanning section 4. The deposition controller 62 that controls the discharge of the evaporation materials by the evaporation sources 311, 321 to 325, and 331 to 333 stops the discharge of the evaporation materials by the evaporation sources 311, 321 to 325, and 331 to 333, on the basis of the test results by the deposition tester 64.

This makes it possible to improve the material ratio of the evaporation materials by stopping, when the deposition tester 64 determines a specific one of the constituent layers 82, 831 to 835, and 841 to 843 to be abnormal, the discharge of the evaporation materials onto the position of the constituent layers 82, 831 to 835, and 841 to 842 by the evaporation sources 321 to 325, and 331 to 333 that are located on the downstream side.

Further, in the apparatus for manufacturing an organic EL device 100 according to this embodiment, in the case where no displacement of the substrate 81 occurs in deposition, the evaporation materials are deposited while the revolution speed of the shielding section 5 and the rotational speed of the support roller (can roller) 22 are set equal to each other. In contrast, in the case where the substrate 81 is displaced in deposition, the influences of the displacement can be corrected by detecting the displacement and changing the revolution speed of the shielding section 5 corresponding to the displacement.

It is a matter of course that the deposition data processing apparatus, the apparatus and the method for manufacturing an organic EL device according to the present invention are not limited to the aforementioned embodiments, and various modifications can be made without departing from the gist of the present invention. Further, the configurations, methods, and the like, of various modifications described below, of course, may be optionally selected for use in the configurations, methods, and the like, of the aforementioned embodiments.

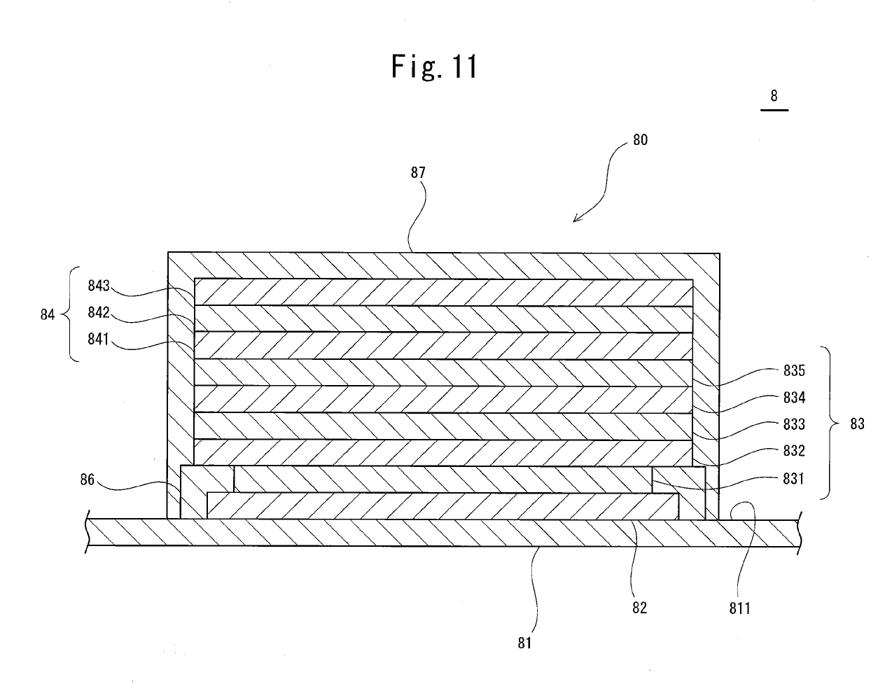

For example, the apparatuses and the manufacturing method according to the present invention may have a configuration in which an edge cover-deposition unit is provided downstream of the first deposition unit 31, and a sealing layer-deposition unit is provided downstream of the third deposition unit 33. Thus, as shown in FIG. 11, an edge cover 86 that covers the periphery of the anode layer 82 so as to prevent the contact between the anode layer 82 and the cathode layer 84, and a sealing layer 87 that covers the layers 82 to 84 so as to prevent the contact of the layer 82 to 84 with the air may be formed on the organic EL device 8 as a manufactured product.

As a material for forming the edge cover 86, silicon oxide (SiOₓ), molybdenum trioxide (MoO₃), and vanadium pentoxide (V₂O₅) can be mentioned, for example.

As a material for forming the sealing layer 87, molybdenum trioxide (MoO₃), silicon oxide nitride (SiNOₓ), and silicon oxycarbide (SiOC) can be mentioned, for example. Examples of SiOₓ include SiO₂, and examples of SiNOₓ include SiNO.

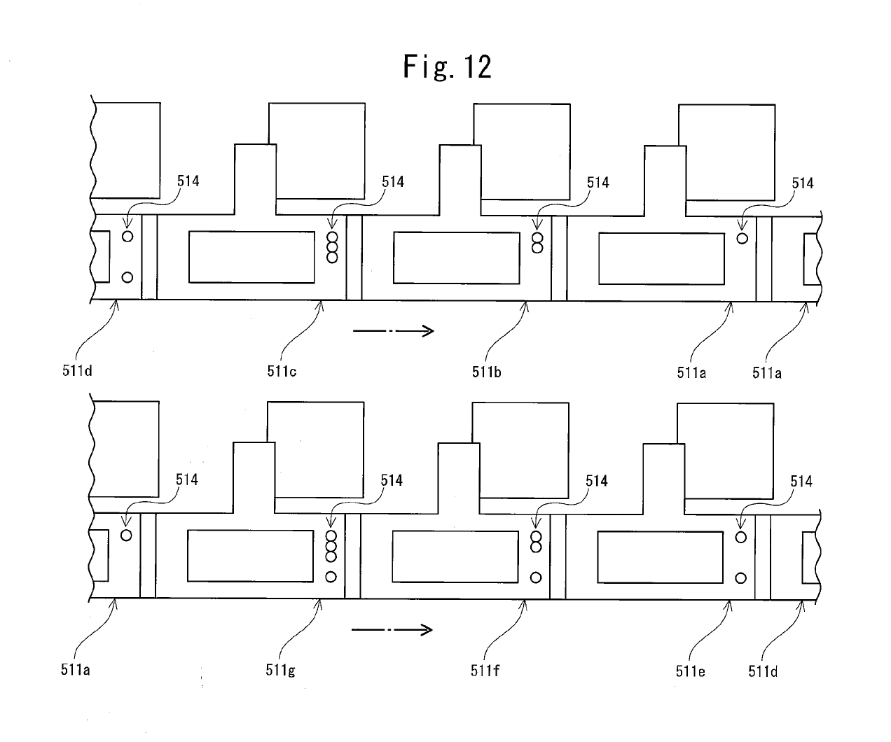

Further, the apparatuses 100 and 101, and the manufacturing method according to the aforementioned embodiments have a configuration in which the second opening 5a is formed by the gap between the shields 511. However, there is no limitation to such a configuration. For example, as shown in FIG. 12, the second opening 514 may be provided within each of the shielding members 51. FIG. 12 shows the state where the shielding members 51 are located at their shielding positions.

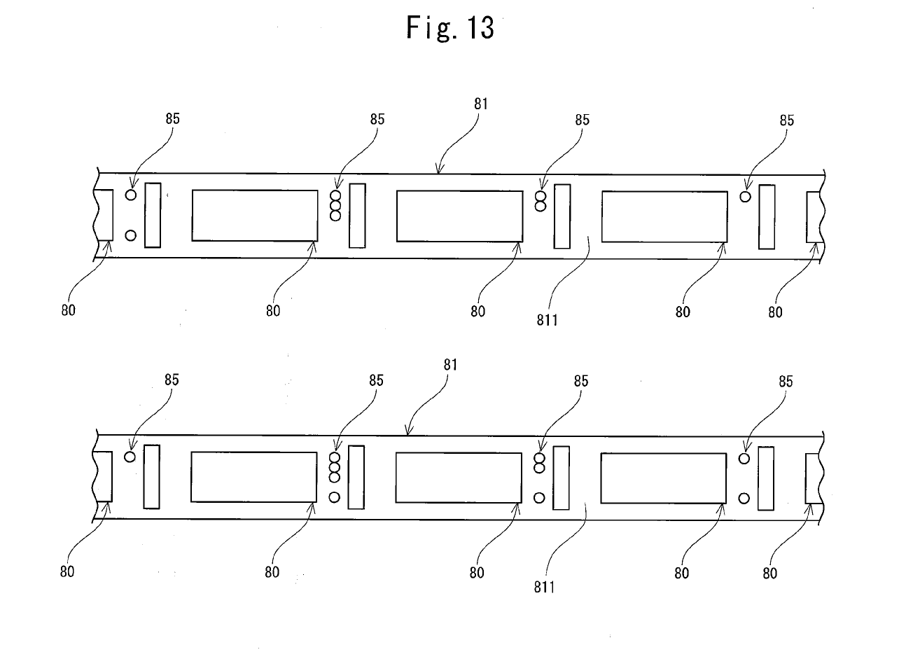

Further, as shown in FIG. 12, the second opening 514 may have a different shape in each of the shielding members 51. According to such a configuration, the scan trigger 85 is formed to have a different shape in each of the six shields 511 (511a to 511f), as shown in FIG. 13. Therefore, when the deposition tester 64 determines the deposition state of a specific one of the constituent layers 82, 831 to 835, and 841 to 843 to be abnormal, it is possible to specify which of the shielding members 51 (511a to 511f) has caused the abnormality.

Further, the apparatuses 100 and 101, and the manufacturing method according to the aforementioned embodiments have a configuration in which the scan trigger 85 is formed by deposition of the evaporation materials on the substrate 81. However, there is no limitation to such a configuration. For example, a tag or the like may be attached to the substrate 81 before it is fed from the substrate feeder 21.

Further, the apparatuses 100 and 101, and the manufacturing method according to the aforementioned embodiments have a configuration in which the shield 511 is a flip-type rotatable shield plate. However, there is no limitation to such a configuration. For example, the shielding section 5 may have a configuration in which the shield 511 is slid in a specific direction, thereby being switched between the shielding position and the unshielding position. Further, the shielding section 5 may be configured as a strip-shaped shadow mask that is conveyed integrally with the substrate 81 while being in tight surface-to-surface contact with the substrate 81.

Further, the apparatuses 100 and 101, and the manufacturing method according to the aforementioned embodiments have a configuration in which the scanning section 4 scans all the constituent layers 82, 831 to 835, and 841 to 843. However, there is no limitation to such a configuration. For example, the scanning section 4 needs only to be configured to scan at least two constituent layers.

### REFERENCE SIGNS LIST

1: Vacuum Chamber

2: Conveying Section

3: Deposition Section

4: Scanning Section

5: Shielding Section

5a: Second Opening

6: Processor

8: Organic EL Device

11: Vacuum Chamber

12: Vacuum Generator

21: Substrate Feeder

22: Support Roller (Can Roller)

23: Support Roller (Conveying Roller)

24: Substrate Collector

31, 32, 33: Deposition Unit

41: Scanner

51: Shielding Member

52: Switching Mechanism

61: Conveyance Controller

62: Deposition Controller

63: Scanner Controller

64: Deposition Tester

65: Accumulator

71: Input Unit

72: Output Unit

80: Organic EL Element

81: Substrate

82: Anode Layer

83: Organic EL Layer

84: Cathode Layer

85: Scan Trigger

86: Edge Cover

87: Sealing Layer

100: Apparatus For Manufacturing Organic EL Device

101: Deposition Data Processing Apparatus

221: Drive Shaft

311, 321, 322, 323, 324, 325, 331, 332, 333: Evaporation Source

511: Shield

512: First Opening

513: Base

514: Second Opening

521: Body

522: First Rotor

523: Second Rotor

524: First Link

525: Second Link

526: Cam Follower

527: Cam

527a: First Region

527b: Second Region

527c: Third Region

527d: Fourth Region

641: Information Storage

642: Determination Unit

811: Deposition Surface

831: Hole Injection Layer

832: Hole Transporting Layer

833: Light Emitting Layer

834: Electron Transporting Layer

835: Electron Injection Layer

841, 842, 843: Cathode Layer-Constituent Layer

1. A deposition data processing apparatus configured to process deposition data of a plurality of organic EL elements that are formed in line in a longitudinal direction of a strip-shaped substrate being conveyed by depositing evaporation materials on the substrate, the apparatus comprising:
a scanning section configured to scan at least two of a plurality of constituent layers that constitute each of the organic EL elements; and
a processor configured to accumulate data of the respective constituent layers scanned by the scanning section at a specific position in the longitudinal direction of the substrate, as data of a specific one of the organic EL elements.

2. An apparatus for manufacturing an organic EL device, comprising:
the deposition data processing apparatus according to claim 1;
a conveying section configured to convey the substrate; and
a plurality of evaporation sources configured to discharge evaporation materials onto the substrate being conveyed, wherein
the evaporation materials discharged from the evaporation sources are deposited on the substrate so as to form each of the organic EL elements including the plurality of constituent layers.

3. The apparatus for manufacturing an organic EL device according to claim 2, further comprising:
a shielding section having a shielding member configured to shield the substrate, wherein
the shielding member includes a first opening configured to expose a constituent layer-forming position of the substrate at which the constituent layers are formed, so that the evaporation materials are deposited on the constituent layer-forming position of the substrate,
the shielding section includes, in order to form a scan trigger that triggers the scanning section to scan the constituent layers, a second opening configured to expose a trigger-forming position of the substrate at which the scan trigger is formed, so that the evaporation materials are deposited on the trigger-forming position of the substrate, and
the scanning section scans the constituent layers on the basis of detection of the scan trigger.

4. The apparatus for manufacturing an organic EL device according to claim 2, wherein
the processing apparatus further includes:
a deposition controller configured to control the discharge of the evaporation materials by the evaporation sources; and
a deposition tester configured to test deposition states of the constituent layers on the basis of the data of the constituent layers scanned by the scanning section, wherein
the deposition controller is configured to stop the discharge of the evaporation materials by the evaporation sources on the basis of the test results by the deposition tester.

5. A method for manufacturing an organic EL device, using the apparatus for manufacturing an organic EL device according to claim 2.

6. The apparatus for manufacturing an organic EL device according to claim 3, wherein
the processing apparatus further includes:
a deposition controller configured to control the discharge of the evaporation materials by the evaporation sources; and
a deposition tester configured to test deposition states of the constituent layers on the basis of the data of the constituent layers scanned by the scanning section, wherein
the deposition controller is configured to stop the discharge of the evaporation materials by the evaporation sources on the basis of the test results by the deposition tester.

7. A method for manufacturing an organic EL device, using the apparatus for manufacturing an organic EL device according to claim 3.

8. A method for manufacturing an organic EL device, using the apparatus for manufacturing an organic EL device according to claim 4.

9. A method for manufacturing an organic EL device, using the apparatus for manufacturing an organic EL device according to claim 6.
